(19) United States
(12) Patent Application Publication
(10) Pub. No.: US 2026/0180558 A1
(43) Pub. Date: Jun. 25, 2026

(54) Double-Delta Filter Systems and Methods

(71) Applicant: Datadog Inc., New York, NY (US)

(72) Inventors: Colin Andrew Nichols, Ridgefield, CT (US); Hippolyte Marie Alexandre Barraud, Weehawken, NJ (US); Jun Yuan, Plainview, NY (US); Pawel Knap, Boston, MA (US); Maxim Sokolov, San Carlos, CA (US); Mathias Hailu Thomas, Fairfax Station, VA (US)

(21) Appl. No.: 18/999,641

(22) Filed: Dec. 23, 2024

(51) Int. Cl. H03H 17/02; H03M 7/30

(52) U.S. Cl. CPC H03H 17/02; H03M 7/30

(57) ABSTRACT

The technology provides an efficient delta-of-delta compression process, which is designed to take advantage of large register configurations such as 128-bit or 256-bit registers. The process employs predictors to predict particular data values, such as for a timeseries of data. The timeseries is stored as a vector of points in memory. Predictors leverage instruction size and register size so that data storage is highly efficient, and processing latency is minimized or otherwise reduced. The process can be particularly beneficial for certain architectures, including single instruction, multiple data (“SIMD”) architectures, as it allows for the reuse of operands between iterations. This reduces the number of register loads required by the processing system, such as by omitting one or more load instructions that would otherwise be required. Moreover, decompression of compressed data generated by this approach can be performed very quickly, which can be important for data retrieval.

### BACKGROUND

Compression techniques are applicable to a wide variety of computing situations. Some are lossy (e.g., MP3 or jpg) while others are lossless (e.g., png or gzip). Compression can significantly reduce data storage and transmission costs, and can help speed up queries or other operations. General-purpose compression algorithms are often designed to generate a concise representation of some input data. In other words, such algorithms “shrink” the data into a more concise form. This can be accomplished by analyzing the data to identify patterns, identify repeated data, or predict what comes next. However, in many instances such identification or prediction is inefficient or otherwise fails to account for certain constraints or issues, such as noise in the data. The result may be suboptimal compression. In turn, this can impact data storage, latency, and/or subsequent analysis of the data.

### BRIEF SUMMARY

Aspects of the technology use predictors as part of a delta-of-delta compression process. The predictors leverage instruction size and register size to achieve significant benefits for both data storage and latency, thereby improving the functioning of the computer system. This is particularly beneficial for certain architectures, including single instruction, multiple data (“SIMD”) architectures, in which multiple processing elements are configured to perform the same operation simultaneously on multiple data points.

According to one aspect, a computer-implemented double-delta filtering method is provided, which comprises: obtaining, by one or more processors of a computing system, a timeseries set of points; storing, by the one or more processors, a first point of the timeseries set of points in a first hardware register, wherein the first point is stored uncompressed; performing, by the one or more processors, an xor operation on a second point of the timeseries and the first point to generate a modified second point; storing, by the one or more processors, the modified second point in a second hardware register; performing, by the one or more processors, double-delta filtering of a third point of the timeseries using a scalar instruction and storing the third point in a third hardware register; performing, by the one or more processors, double-delta filtering of a fourth point of the timeseries using a scalar instruction and storing the fourth point in a fourth hardware register; performing, by the one or more processors, for each subsequent point in the timeseries, double delta filtering using a stored pair of prior points, in which the stored pair of prior points are not sequential; and storing a result of the double delta filtering method in a subsequent hardware register.

The method may further comprise: performing, by the one or more processors, compression on the result to obtain a compressed set of data; and storing the compressed set of data is a compression buffer. Here, the result of the double delta filtering method may include more 0's than 1's, and the method may further include performing the compression on the result so that 0 values are each stored in 2 bits. The compression may be lossless.

In one example, the method may further comprise performing lossless decompression on the compressed set of data. In another example, when the subsequent point is an i^{th} point of the timeseries, a first one of the pair of prior points may be an i−2 point and a second one of the pair of prior points may be an i−4 point relative to the i^{th} point. In a further example, each point of the timeseries set of points is stored as a multi-tuple including at least one timestamp and a value. Here, a size of the multi-tuple may be less than a register size. In one scenario, the multi-tuple is a 3-tuple.

In one scenario, performing the double delta filtering using the stored pair of prior points applies a minimum number of load instructions. Each of the first, second, third and fourth hardware registers may be a respective single instruction, multiple data (SIMD) register. Here, the subsequent hardware register may also be a SIMD register.

In a further example, the method further comprises identifying a register size for a single instruction, multiple data (SIMD) implementation.

According to another aspect of the technology, a processing system configured to implement a double-delta filtering method is provided. The processing system comprises memory configured to store a timeseries of data as a vector of points, and one or more processors operatively coupled to the memory. The one or more processors are configured to: store a first point of the timeseries in a first hardware register of the memory, wherein the first point is stored uncompressed; perform an xor operation on a second point of the timeseries and the first point to generate a modified second point; store the modified second point in a second hardware register of the memory; perform double-delta filtering of a third point of the timeseries using a scalar instruction and store the third point in a third hardware register of the memory; perform double-delta filtering of a fourth point of the timeseries using a scalar instruction and store the fourth point in a fourth hardware register of the memory; perform, for each subsequent point in the timeseries, double delta filtering using a stored pair of prior points, in which the stored pair of prior points are not sequential; and store a result of the double delta filtering method in a subsequent hardware register of the memory.

The one or more processors may be further configured to perform compression on the result to obtain a compressed set of data, and store the compressed set of data is a compression buffer. In one scenario, the one or more processors implement a predictor module configured to predict a next datapoint from a set of previous datapoints in the timeseries. The one or more processors may further implement a packer module to perform the compression on the result.

Each point of the timeseries can be stored as a multi-tuple including at least one timestamp and a value. Performance of the double delta filtering using the stored pair of prior points may be done by applying a minimum number of load instructions. 20. Moreover, each of the first, second, third and fourth hardware registers may be a respective single instruction, multiple data (SIMD) register.

### BRIEF DESCRIPTION OF THE DRAWINGS

FIG. 1 illustrates an exemplary timeseries stored as a vector of points in accordance with aspects of the technology.

FIG. 2 illustrates another exemplary timeseries stored as a vector of points in accordance with aspects of the technology.

FIG. 3A illustrates an exemplary predictor module in accordance with aspects of the technology.

FIG. 3B illustrates an exemplary packer module in accordance with aspects of the technology.

FIG. 4 illustrates an example of storage of multi-tuple elements in different parts of a register, in accordance with aspects of the technology.

FIG. 5 illustrates another example of storage of multi-tuple elements in different parts of a register, in accordance with aspects of the technology.

FIGS. 6A-B illustrate an example computing system in accordance with aspects of the technology.

FIG. 7 illustrates an example method in accordance with aspects of the technology.

### DETAILED DESCRIPTION

In many situations involving data storage, transmission and processing, data is collected in time-series. In particular, data may be collected as a series of data points either at regular or irregular intervals, e.g., milliseconds, seconds, hours, days, etc. Evaluation of this data can identify patterns, trends and/or relationships between different elements of the data. This can be particularly useful to evaluate Internet traffic, infrastructure monitoring (e.g., CPU usage, available disk space), etc., as there may be millions or billions of data points (or more) to be stored, transmitted and/or processed. As a result, the system may provide users situational awareness of potential usage, storage or other issues, for instance by triggering an alert if a part of the system is not running effectively or efficiently, or if resources become constrained (e.g., available memory becomes limited).

Timeseries compression algorithms can involve compression of floating-point data. Delta encoding, also known as delta compression, may be employed. Delta encoding takes the difference between a current data point and the prior data point (i.e., between two sequential data points). The resultant values may be stored using some form of “varint” encoding, for instance by representing integers (e.g., unsigned 32-bit or 64-bit integers) using a variable number of bytes, in which smaller values use fewer bytes.

In some instances, delta encoding may involve the use of delta-of-delta compression (or “delta-delta encoding”), which is effectively a second order derivative. Here, delta encoding is performed a second time on the delta-encoded data. The system seeks to predict the next data value based on what is already known. The goal is to take the timeseries of data and try to make it look as close to a set of 0s as possible (smaller numbers), which leads to more effective and efficient compression.

Certain timeseries compression algorithms are susceptible to noise in the data. For instance, having as little as 5% noise can have a huge effect on timeseries compression performance. Such approaches are typically slow, as they involve many bit-level operations performed by the SIMD architecture.

The double-delta approach discussed herein is designed to take advantage of large register configurations. By way of example only, this includes but is not limited to large register configurations such as 128-bit or 256-bit SIMD-type registers. Larger (or smaller) register configurations may be employed. The double-delta process is performed using larger groups of registers and a wider or otherwise extended “stride” of data points than prior approaches, which allows for the reuse of operands between iterations. This reduces the number of register loads required by the processing system (e.g., by omitting several SIMD load instructions), which enables the approach to run much faster than other approaches. This is an important technical benefit to the processing system. For instance, for decompression (e.g., in response to a query or other request received by the system), the approach can be more than double the speed of an optimized conventional/scalar implementation.

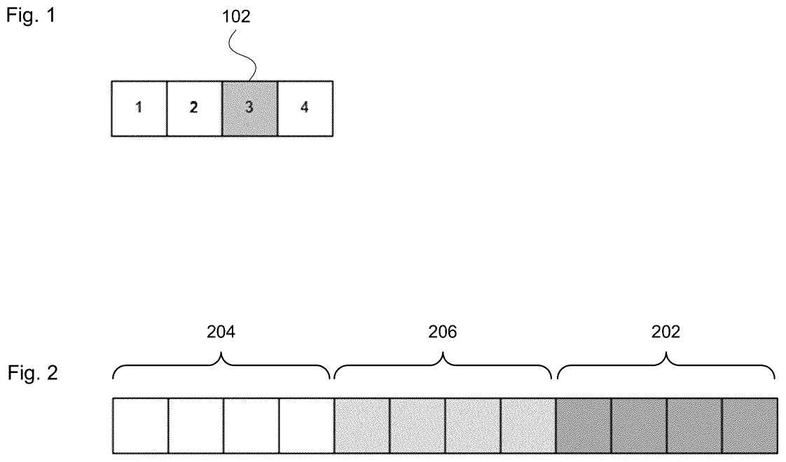

According to one aspect of the technology, a timeseries is stored as a vector of points. At a high level, the goal is to predict a particular data value. For instance, in the example illustrated in FIG. 1, in order to predict the value for point #3 (shaded) labeled as 102, the system can take the difference between points 1 and 2, and add it to the value for point 2 to predict the value for point 3.

Ideally, this can be done for four data points at a time in a SIMD-type approach. Thus, in the example shown in FIG. 2, the four rightmost blocks (dark gray, collectively set 202) would be predicted based on both the first four blocks (white, collectively set 204) and second four blocks (light gray, collectively set 206).

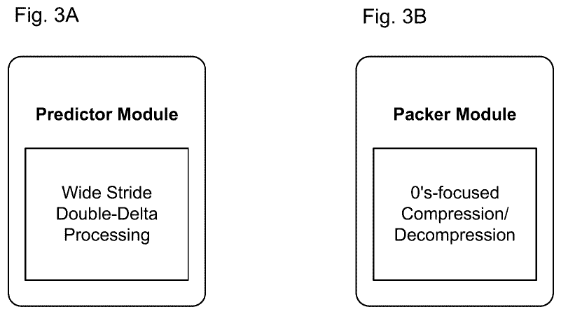

In accordance with a first approach, the system may employ both a predictor module and a packer module, as shown in FIGS. 3A and 3B, respectively. The predictor module is implementable by the computing system so that it is configured to employ wide stride double-delta processing to predict the next datapoint, v (n+1), from a set of previous datapoints. It uses block-predict encoding to function effectively in the presence of noise, in contrast to prior approaches. First, the predictor finds the average delta, e.g., over the past 4 datapoints: e.g., dv=(data[n−4]−data[n−1])/3.0. This interval of points provides noise resistance. The predictor module would then extrapolate the next 4 points. For each prediction, the system uses an xor operation to calculate the “error” between the prediction and the actual data point. Packing by the packing module is byte-based, where error terms are packed in blocks of, e.g., 4 points. By working in blocks, the packer module is able to amortize the cost of control bits over the length of the block. This allows for efficiency with certain types of inputs, and for the process to achieve sub-bit-per-value compression on certain inputs. The packer module is implementable by the computing system to efficiently compress the data generated by the predictor module (and/or decompress previously compressed data). The compression scheme may be selected so that it is particularly effective at compressing (or decompressing) data that has a high rate of 0's (e.g., at least 50% 0's, more than 60-70% 0's, or an even greater percentage of 0's).

In one scenario, the packer may be chosen (e.g., at runtime) to suit the data produced by the predictor module. For instance, statistics such as timeseries length or the percentage of 0's in the data could be used to select an optimal packer for the specific data that has been produced by the predictor module. Alternatively or additionally, a packer may be chosen (e.g., at runtime) to suit a specific application of interest. For example, long-term storage applications may benefit from a packer that creates more efficient (smaller) representations, at the expense of compress/decompress time. Or, for purposes of caching or oft-accessed data, the opposite tradeoff may be preferred: a quick compression/decompression at the cost of extra space required for the packed data.

In accordance with a second, enhanced approach, the predictor module may be configured to look farther back than the above-discussed approach. This is done using a wider (extended) stride of data points, e.g., while operating on four data points at a time. Here, for each individual point, the system is configured to calculate a linear approximation such as based on prior points 4 and 8. This approach ties back to different hardware registers of the computing system, such as SIMD-type registers. In other scenarios, even wider strides can be used to calculate an approximation.

Instead of using point [i−1] and point [i−2] as inputs per the first approach, the enhanced approach is configured to use point [i−2] and point [i−4]. Using this wider (extended) stride is mathematically correct, albeit with different characteristics than the first approach. Beneficially, the enhanced approach allows for the optimization of the decoding function, by omitting several load instructions, e.g., SIMD-type load instructions.

Each point may be stored as a multi-element tuple (multi-tuple), such as a 3-tuple of (timestamp, value, version) or a 4-tuple of (timestamp, value, value, version). Depending on the system architecture, each element of the multi-tuple may be a fixed-size element. The size of each element of a particular tuple may be the same size (e.g., 32, 32, 32), different sizes (e.g., 16, 32, 64), or a combination thereof (e.g., 32, 16, 32). By way of example, in a 128-bit register configuration, each element of the multi-tuple may be 32 bits, such as:
[32-bit uint] Timestamp: Second-resolution timestamp for the point
[32-bit float] Value: The value for the data of interest
[32-bit uint] Version: Used to deconflict values in the presence of multiple/updated points with the same timestamp

Here, the multi-tuple is a 3-tuple and considered as one point, although each part of the 3-tuple (e.g., timestamp, value or version) is stored in a separate portion of a given register, such as a SIMD register.

The multi-tuple can be modified to add extra data (e.g., padding) before the multi-tuple, after the multi-tuple, or within the multi-tuple (e.g., between elements). According to one aspect of the technology, an element is used for each 3-tuple and there are four discrete parts used to store each given point in the register. There is a computational benefit to this, because when the width of the modified multi-tuple is the same as the width of the register (e.g., 128-bit or 256-bit), this minimizes the amount of processing required by the system because there is only one load operation for the block of data in the register. Thus, if the register is 128-bits, the 32-bit timestamp, 32-bit value and 32-bit version information can be stored as 3 sub-elements of 32-bits each, with another sub-element of 32 bits that can be allocated for padding, enhanced value granularity, parity or a checksum, or for other purposes.

Because of the extended stride in the enhanced double-delta implementation and the inclusion of padding/extra data in portions of the SIMD registers where necessary, the data in the registers is aligned such that the system can simply rename variables and pass them on into the next iteration. Put another way, SIMD loads in this approach rarely load the same memory twice, and even when there is an overlap, the overlap is relatively small compared with realigning the data every byte. This extended stride approach beneficially saves cache space and bandwidth, while reducing the overall instruction count significantly. In contrast, a conventional approach would be to load all operands on every iteration, and/or use expensive SIMD shuffle instructions to realign the data in the registers.

Note that the double-delta process can be tailored to the size of the hardware registers used. In one example, the process may include identifying the register size, whether it is for SIMD implementation or other architecture. The identification may be performed directly, such as by querying at runtime to identify one or more parameters of the processing system. Alternatively, the identification may be done indirectly, e.g., according to the type of hardware chip used by the system.

In the first phase of the enhanced approach with a SIMD-type arrangement, the predictor module encodes using a SIMD-accelerated delta-of-delta filter that operates on the points. For typical timeseries data gathered at regular intervals, the delta-of-delta filter often produces more zeros than ones (e.g., more than 50% 0's, such as at least 60-70% 0's).

The process takes advantage of this via compression that is highly effective when there are mostly 0's to compress. Thus, in the second phase of the process, the packer module compresses the data using, e.g., Stream VByte or another suitable compression scheme. Stream VByte is described in the article by Lemire et al. entitled “Stream VByte: Faster Bye-Oriented Integer Compression”, published Sep. 27, 2017. For instance, Stream VByte may compress each 32-bit value individually, similar to a varint compression approach. However, it special-cases a 0 value to just 2 bits. Thus, if a value is nonzero, the scheme determines the minimum n that it fits into 2n, e.g., where n may be Aug. 16, 1932. The value is then packed into n bits and the 2 metadata bits are stored separately. All this is can be accomplished, e.g., via SIMD instructions.

Consider the following example sequence:

| Timestamp | Value | Version |
|---|---|---|
| 165 | 99 | 1000 |
| 180 | 99 | 1002 |
| 195 | 99 | 1006 |
| 210 | 99 | 1008 |
| 225 | 99 | 1011 |
| 240 | 99 | 1015 |
| 255 | 99 | 1016 |
| 270 | 99 | 1020 |

The algorithm implemented by the predictor module starts by storing the first point uncompressed (here, the first point is [165, 99, 1000]), while the second point is stored with a xor of the previous point, and the third and fourth points are stored using a double delta filter (e.g., using scalar (non-SIMD) instructions). An xor operation is used instead of subtraction, which avoids negative numbers, since negative numbers do not compress well. Byte swapping or zigzag operations could alternatively be used instead of the xor operation.

The reason to store the first point uncompressed is because it is a “starting point” for the algorithm. It sets the initial conditions for all subsequent operations. For the 2nd point, there are not enough “trailing” datapoints to calculate a double-delta. The system can calculate the delta from the first point, which still allows for some compression of the point. For the 3rd and 4th points, there is enough trailing data to calculate the double-delta. However, there is still not enough trailing data to use the full “wide double delta” SIMD approach. So instead, the predictor module of the system can calculate a traditional double-delta using traditional scalar CPU instructions.

The main loop of the algorithm implemented by the predictor module begins with the fifth point (here, [255, 99, 1011]). Starting with this point, the predictor module of the system performs a double delta filter on each subsequent point, filtering two points per iteration doing the following operations:
1) Load the next two points in vec1 (points[i], points[i+1]) (e.g. [225, 99, 1011, 240, 99, 1015])
2) Load 1st+2nd previous points in vec2 (points[i−2], points[i−1]) (e.g., [195, 99, 1006, 210, 99, 1008])
3) Load 3rd+4th previous points in vec3 (points[i−4], points[i−3]) (e.g., [165, 99, 1000, 180, 99, 1002)
4) Perform a vector SIMD subtraction operation vec2−vec3=tmp1 (e.g., tmp1=[30, 0, 6, 30, 0, 6])
5) Perform a vector SIMD addition operation vec2+tmp1=tmp2 (e.g. tmp2 [225, 99, 1012, 240, 99, 1014])
6) Perform a vector SIMD xor operation vec1\hat{ }tmp2=result (e.g., result=[0, 0, 7, 0, 0, 1])
7) Store result into an output buffer.
   For any trailing data, the system can filter any leftover points without SIMD instructions.

The buffered output of the above double-delta filter is fed to the packer module. As noted above, the packer module is configured to perform highly efficient compression process, such as via Stream VByte or another compression scheme, to produce a shortened output. In one scenario, the compression scheme uses special-case 0 values so that they are stored in only 2 bits. For low-noise data, the double-delta filter approaches discussed herein produce a high rate of 0s (e.g., at least 60-70% 0's), which means that the data can be compressed in a highly efficient manner by the packer module. The compressed data may be stored in a compression buffer.

The decoder process reverses all encoding operations and reconstructs the input faithfully. In other words, the decompression is lossless. Thus, the compressed information associated with a given timeseries of data can be decompressed and provided in response to a data request or other query. The packer module may run the compressed buffer through a Stream VByte decoder (or the decoder for any other suitable compression process). This produces an unpacked, but still double-delta-encoded, data stream.

The unpacked data stream then undergoes double-delta decoding, which may be performed by the predictor module of the computing system. This decoding process may be performed as follows. The first input item is an unencoded point, and thus would be copied directly into the output buffer. The second input item is xor′ed with the first output point and stored as the 2nd output point. The third and fourth input items are decoded using scalar double-delta to produce the third and fourth output points.

From the fifth point onwards, the module performs a double delta filter on each input item, outputting two points per iteration. There are 4 variables used in the main decoding loop. In one scenario, all 4 variables may be 256-bit wide, backed by hardware SIMD registers. The 4 variables can be identified as follows. “prev”, which is “output [i−2]”; the newer historical point for double-delta. “prevprev”, which is “output [i−4]”; the older historical point for double-delta. “deltas”, which is “input [i]”, the encoded input data representing the next points. And “tmp”, which is a scratch variable used to store the decoded output points.

Before the loop begins, the module initializes “prev” and “prevprev”, which correspond to “output [i−2]” and “output [i−4]”, respectively. These are parameters for the double-delta operation, along with the relevant data from the input buffer:
1) Load “output [i−2]” into prev
2) Load “output [i−4]” into prevprev

Once initialization is complete, the main loop is executed. This can involve performing the following operations on each iteration:
1) Load “input [i]” into deltas
2) Subtract “prevprev” from “prev” and put the result in “tmp”
3) Add “prev” and “tmp”, and put the result in “tmp”
4) Bitwise xor “tmp” and “deltas”, and put the result in “tmp”
5) Store “tmp” to “output [i]”, e.g., in a decompression buffer
6) Rename “prev” to “prevprev”
7) Rename “tmp” to “prev”
   The process can filter any leftover points (non multiple of twos) without SIMD instructions.

This decompression algorithm has been configured to optimize decoding speed. For an SIMD architecture, the decoding loop requires only 1 load, 1 store, and a few SIMD operations. The result is remarkable decoding speed. The most notable optimizations are: (i) the ability to use “tmp” at the end of one iteration, as “prev” in the following iteration, and (ii) the ability to use “prev” at the end of one iteration, as “prevprev” in the following iteration. In contrast, for conventional implementations, obtaining “prev” and “prevprev” for the next loop would require either loading data from cache/memory, or performing expensive SIMD shuffle operations. Because of the extended stride of the above-described double-delta implementation and the inclusion of padding/extra data in the SIMD registers where necessary, the data is aligned such that the system can simply rename variables and pass them on into the next iteration. This saves cache space and bandwidth, and reduces the overall instruction count significantly.

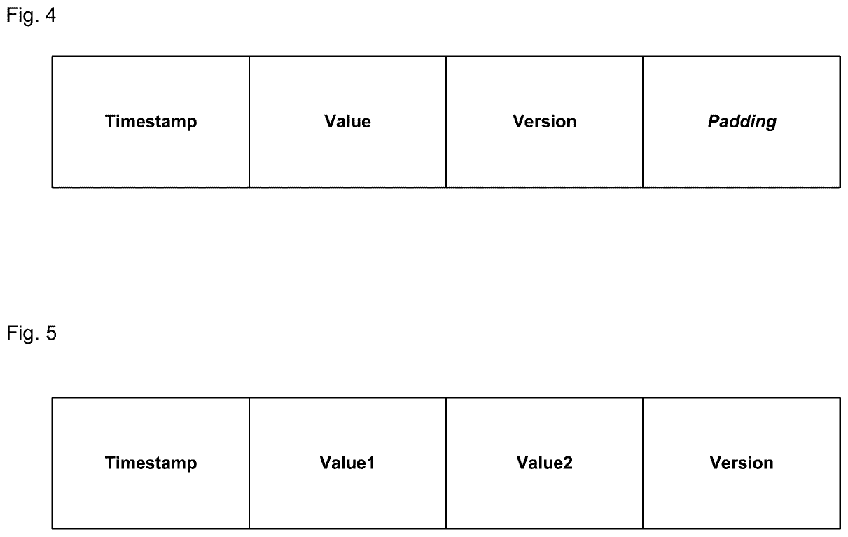

As noted above, the elements of the 3-tuple are stored in different parts of the register (e.g., a SIMD register). Thus, if the first part stores the timestamp, the second part stores the value, and the part register stores the version register, the fourth part may be empty (or include padding). An example of this is shown in FIG. 4.

In one scenario, the timestamp may record the time associated with measurement of the value, while the version may record the ingress time when the data entered the system. According to one aspect of the technology, the size of the data points may vary or otherwise change (e.g., from 32-bit to 64-bit or larger).

In another scenario as shown in FIG. 5, the timestamp and version may each be 32-bit elements, while the value is a 64-bit element (e.g., for enhanced granularity). Here, the data may be stored in the (e.g., SIMD) register using two value fields in adjacent data blocks, while placing the version in the last block of the register.

The processing by the system can be tailored to the size of the hardware registers that are available/utilized. Moreover, the system may operate on different types of processor architectures that have different SIMD or other register sizes (e.g., 128-bit, 256-bit, 512-bit, etc.). As noted above, in one scenario the system may identify the register size directly, such as by querying the CPU at runtime. Or the system may identify the register size indirectly, such as based on the type of hardware chip. Regardless, the system may choose an optimal configuration for the processing in accordance with the register size(s) that is available.

### Example Computing Architecture

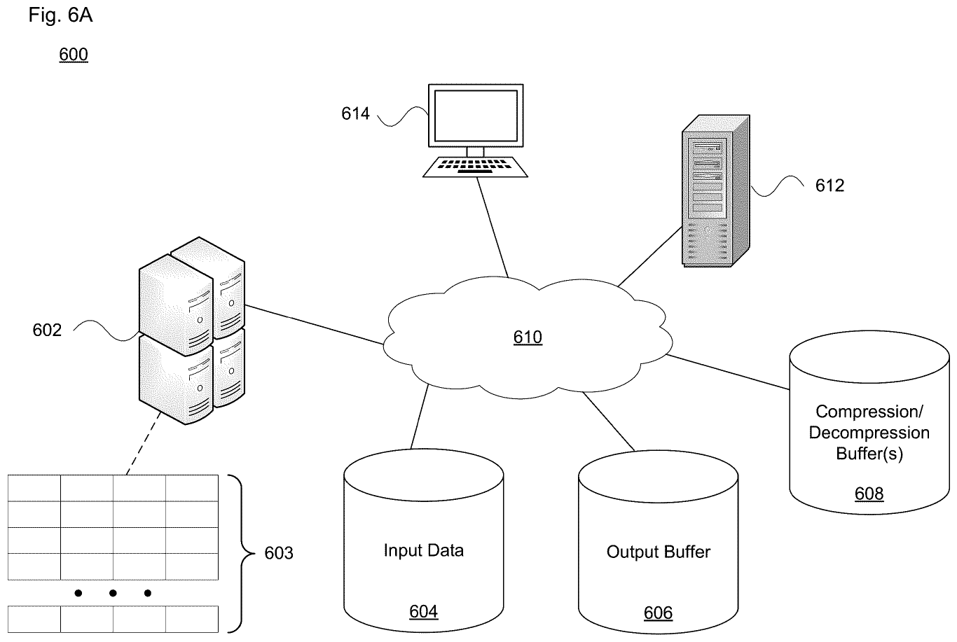

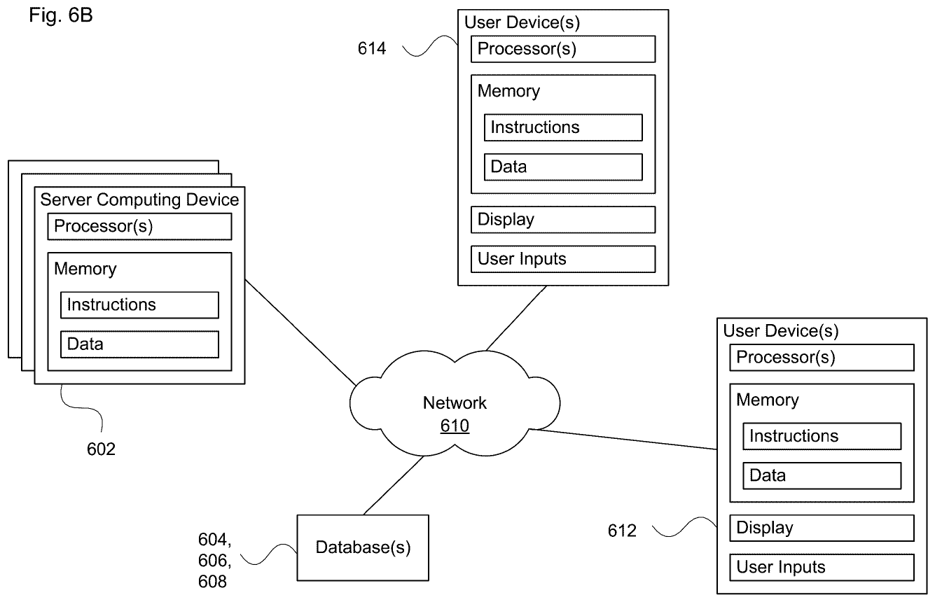

FIGS. 6A-B illustrate an example computing architecture 600 that may be employed with the double-delta filter methods described herein. In particular, FIGS. 6A and 6B are pictorial and functional diagrams, respectively, of an example system 600 that includes a plurality of computing devices and databases connected via a network. For instance, computing device(s) 602 may be a single server farm or a cloud-based server system. As shown in this example, the computing devices 602 may have a specific register configuration 603, such as a SIMD-type register configuration, to store the multi-tuples of input data to be processed by the predictor module and/or the packer module as described herein.

Database 604 may store, e.g., input data such as Internet traffic or infrastructure monitoring information such as CPU usage, available disk space, etc., as discussed herein. Databases 606 and 608 may store partially or fully processed data, and may comprise an output buffer, compression/decompression buffers, etc. The server system may access the databases via network 610. One or more user devices or systems may include a computing system 612 and a desktop computer 614. Other types of user devices may also be employed.

As shown in FIG. 6B, each of the computing devices 602 and 612-614 may include one or more processors, memory, data and instructions. The memory stores information accessible by the one or more processors, including instructions and data (e.g., code to implement the predictor and packer modules, input data, buffered data, processed and compressed data, etc.) that may be executed or otherwise used by the processor(s). The memory may be of any type capable of storing information accessible by the processor(s), including a computing device-readable medium. The memory is a non-transitory medium such as a hard-drive, memory card, optical disk, solid-state, etc. Systems may include different combinations of the foregoing, whereby different portions of the instructions and data are stored on different types of media.

The instructions may be any set of instructions to be executed directly (such as machine code) or indirectly (such as scripts) by the processor(s). For example, the instructions may be stored as computing device code on the computing device-readable medium. In that regard, the terms “instructions”, “methods”, “algorithms”, and “programs” may be used interchangeably herein. The instructions may be stored in object code format for direct processing by the processor, or in any other computing device language or format including scripts or collections of independent source code modules that are interpreted on demand or compiled in advance. The instructions may enable the processor(s) to perform any of the approaches discussed above, including implementation of the predictor and/or packer modules according to the processes disclosed herein.

The processors may be any conventional processors, such as commercially available CPUs, GPUs, TPUs, etc. Alternatively, each processor may be a dedicated device such as an ASIC or other hardware-based processor. Although FIG. 6B functionally illustrates the processors, memory, and other elements of a given computing device as being within the same block, such devices may actually include multiple processors, computing devices, or memories that may or may not be stored within the same physical housing. Similarly, the memory may be a hard drive or other storage media located in a housing different from that of the processor(s), for instance in a cloud computing system of server 602. Accordingly, references to a processor or computing device will be understood to include references to a collection of processors or computing devices or memories that may or may not operate in parallel.

Moreover, reference to “one or more processors” herein includes situations where a set of processors may be configured to perform one or more operations. Any combination of such a set of processors may perform individual operations or a group of operations. This may include two or more CPUs, GPUs and/or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

By way of example, one processor or set of processors may implement the predictor module or one or more operations thereof, while another processor or set of processors may implement the packer module or one or more operations thereof.

The data, such as the multi-tuples of input data (e.g., received as a set of time-series data), may be operated on by the predictor module to generate wide-stride delta-delta encoded data. This can include creating encoded data that has significantly more 0's than 1's (e.g., at least 60-70% 0's). The encoded data may be compressed by the packer module for compact storage, and may be provided to one or more users, for instance users of computers 612 and/or 614, for evaluation of Internet traffic or infrastructure monitoring. As a result, the system may provide the users situational awareness of potential usage, storage or other issues. By way of example, this can include triggering an alert if a part of the user's system is not running effectively or efficiently, or if resources of that system become constrained (e.g., available memory becomes limited).

The computing devices may include all of the components normally used in connection with a computing device such as the processor and memory described above as well as a user interface subsystem for receiving input from a user and presenting information to the user (e.g., text, imagery and/or other graphical elements, audible alerts, etc.). The user interface subsystem may include one or more user inputs and one or more display devices. Other output devices, such as speaker(s) may also provide information to users.

The user-related computing devices (e.g., 612-614) may communicate with a back-end computing system (e.g., server 602) via one or more networks, such as network 610. The network 610, and intervening nodes, may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 602 may include one or more server computing devices having a plurality of computing devices, e.g., a load balanced server farm or cloud computing system, that exchange information with different nodes of a network for the purpose of receiving, processing and transmitting the data to and from other computing devices. For instance, computing device 602 may include one or more server computing devices that are capable of communicating with any of the computing devices 612-614 via the network 610.

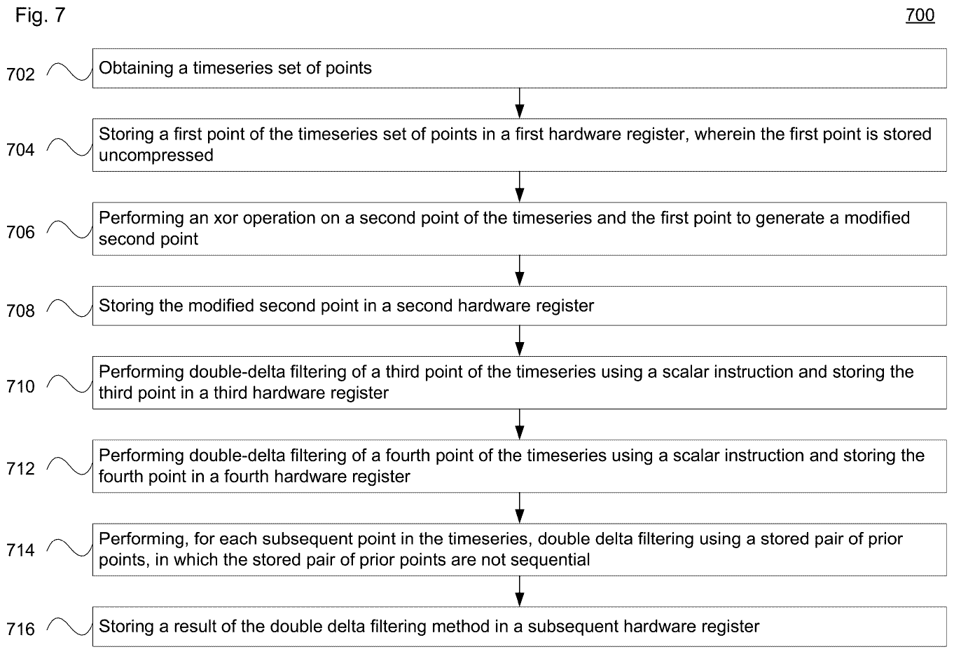

FIG. 7 illustrates an example double delta filtering method 700. As shown at block 702, this method includes obtaining, by one or more processors of a computing system, a timeseries set of points. At block 704, the method includes storing, by the one or more processors, a first point of the timeseries set of points in a first hardware register. The first point is stored uncompressed. At block 706, the method includes performing, by the one or more processors, an xor operation on a second point of the timeseries and the first point to generate a modified second point. At block 708, the method includes storing, by the one or more processors, the modified second point in a second hardware register. At block 710, the method includes performing, by the one or more processors double-delta filtering of a third point of the timeseries using a scalar instruction and storing the third point in a third hardware register, and at block 712 performing double-delta filtering of a fourth point of the timeseries using a scalar instruction and storing the fourth point in a fourth hardware register. Then at block 714 the method includes performing, by the one or more processors, for each subsequent point in the timeseries, double delta filtering using a stored pair of prior points, in which the stored pair of prior points are not sequential. Then at block 716 a result of the double delta filtering method is stored in a subsequent hardware register.

Although the technology herein has been described with reference to particular embodiments and scenarios, it is to be understood that these embodiments and scenarios are merely illustrative of the principles and applications of the present technology. It is therefore to be understood that numerous modifications may be made to the illustrative embodiments and scenarios, and that other arrangements may be devised without departing from the spirit and scope of the present technology as defined by the appended claims.

Moreover, unless expressly stated otherwise, the foregoing examples and arrangements are not mutually exclusive and may be implemented in various ways to achieve unique advantages. These and other variations and combinations of the features discussed herein can be employed without departing from the subject matter defined by the claims. In view of this, the foregoing description of exemplary embodiments should be taken by way of illustration rather than by way of limitation.

The examples described herein, as well as clauses phrased as “such as,” “including” and the like, should not be interpreted as limiting the subject matter of the claims to any specific examples. Rather, such examples are intended to illustrate possible embodiments. Further, the same reference numbers in different drawings can identify the same or similar elements. The processes or other operations may be performed in a different order or concurrently, unless expressly indicated otherwise herein.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. As used in this document, “each” refers to each member of a set or each member of a subset of a set.

1. A computer-implemented double-delta filtering method, comprising:
obtaining, by one or more processors of a computing system, a timeseries set of points;
storing, by the one or more processors, a first point of the timeseries set of points in a first hardware register, wherein the first point is stored uncompressed;
performing, by the one or more processors, an xor operation on a second point of the timeseries and the first point to generate a modified second point;
storing, by the one or more processors, the modified second point in a second hardware register;
performing, by the one or more processors, double-delta filtering of a third point of the timeseries using a scalar instruction and storing the third point in a third hardware register;
performing, by the one or more processors, double-delta filtering of a fourth point of the timeseries using a scalar instruction and storing the fourth point in a fourth hardware register;
performing, by the one or more processors, for each subsequent point in the timeseries, double delta filtering using a stored pair of prior points, in which the stored pair of prior points are not sequential; and
storing a result of the double delta filtering method in a subsequent hardware register.

2. The method of claim 1, further comprising:
performing, by the one or more processors, compression on the result to obtain a compressed set of data; and
storing the compressed set of data is a compression buffer.

3. The method of claim 2, wherein:
the result of the double delta filtering method includes more 0's than 1's; and
performing the compression on the result so that 0 values are each stored in 2 bits.

4. The method of claim 3, wherein the compression is lossless.

5. The method of claim 2, further comprising:
performing lossless decompression on the compressed set of data.

6. The method of claim 1, wherein, when the subsequent point is an i^{th} point of the timeseries, a first one of the pair of prior points is an i−2 point and a second one of the pair of prior points is an i−4 point relative to the i^{th} point.

7. The method of claim 1, wherein each point of the timeseries set of points is stored as a multi-tuple including at least one timestamp and a value.

8. The method of claim 7, wherein a size of the multi-tuple is less than a register size.

9. The method of claim 7, wherein the multi-tuple is a 3-tuple.

10. The method of claim 1, wherein performing the double delta filtering using the stored pair of prior points applies a minimum number of load instructions.

11. The method of claim 1, wherein each of the first, second, third and fourth hardware registers is a respective single instruction, multiple data (SIMD) register.

12. The method of claim 11, wherein the subsequent hardware register is a SIMD register.

13. The method of claim 1, further comprising identifying a register size for a single instruction, multiple data (SIMD) implementation.

14. A processing system configured to implement a double-delta filtering method, the processing system comprising:
memory configured to store a timeseries of data as a vector of points; and
one or more processors operatively coupled to the memory, the one or more processors being configured to:
store a first point of the timeseries in a first hardware register of the memory, wherein the first point is stored uncompressed;
perform an xor operation on a second point of the timeseries and the first point to generate a modified second point;
store the modified second point in a second hardware register of the memory;
perform double-delta filtering of a third point of the timeseries using a scalar instruction and store the third point in a third hardware register of the memory;
perform double-delta filtering of a fourth point of the timeseries using a scalar instruction and store the fourth point in a fourth hardware register of the memory;
perform, for each subsequent point in the timeseries, double delta filtering using a stored pair of prior points, in which the stored pair of prior points are not sequential; and
store a result of the double delta filtering method in a subsequent hardware register of the memory.

15. The processing system of claim 14, wherein the one or more processors are further configured to:
perform compression on the result to obtain a compressed set of data; and
store the compressed set of data is a compression buffer.

16. The processing system of claim 15, wherein the one or more processors implement a predictor module configured to predict a next datapoint from a set of previous datapoints in the timeseries.

17. The processing system of claim 16, wherein the one or more processors further implement a packer module to perform the compression on the result.

18. The processing system of claim 14, wherein each point of the timeseries is stored as a multi-tuple including at least one timestamp and a value.

19. The processing system of claim 14, wherein performance of the double delta filtering using the stored pair of prior points applies a minimum number of load instructions.

20. The processing system of claim 14, wherein each of the first, second, third and fourth hardware registers is a respective single instruction, multiple data (SIMD) register.
